(19) United States
(12) Patent Application Publication
(10) Pub. No.: US 2016/0153119 A1
(43) Pub. Date: Jun. 2, 2016

(54) Epitaxial Structure and Growth Method of Group-III Nitrides

(71) Applicant: XIAMEN SANAN OPTOELECTRONICS TECHNOLOGY CO., LTD., Xiamen (CN)

(72) Inventors: YANHAO DU, Xiamen (CN); MENG-HSIN YEH, Xiamen (CN); CHEN-KE HSU, Xiamen (CN); CHIH-WEI CHAO, Xiamen (CN); WENYU LIN, Xiamen (CN); YI-SHIN YE, Xiamen (CN); JEN-CHUN YANG, Xiamen (CN); JIANMING LIU, Xiamen (CN)

(73) Assignee: XIAMEN SANAN OPTOELECTRONICS TECHNOLOGY CO., LTD., Xiamen (CN)

(21) Appl. No.: 15/016,261

(22) Filed: Feb. 4, 2016

Related U.S. Application Data
(63) Continuation of application No. PCT/CN2014/081768, filed on Jul. 7, 2014.

(30) Foreign Application Priority Data
Aug. 7, 2013 (CN) 201310339115.9

(51) Int. Cl. C30B 25/18; C30B 29/06; C30B 29/68; C30B 29/38; C30B 29/10; C30B 25/14; C30B 29/40

(52) U.S. Cl. CPC C30B 25/183; C30B 25/14; C30B 29/06; C30B 29/406; C30B 29/403; C30B 29/38; C30B 29/10; C30B 29/68

(57) ABSTRACT

A Group-III nitrides epitaxial structure includes a Si substrate, and a Group-III nitrides layer disposed over the Si substrate, wherein an interface structure of “coexistence of Al atoms and SiₓN_{y}” between the Si substrate and the Group-III nitrides. Al atoms are configured to be absorbed to the Si substrate and connect the Group-III nitrides; and SiₓN_{y} are configured to release mismatch stress caused by heteroepitaxy. A fabricating method comprises: (1) providing a Si substrate; (2) forming an interface structure over a surface of the Si substrate , wherein the interface structure is arranged with both Al atoms and SiₓN_{y}, which are then cladded by an AlN epitaxial layer; and (3) growing Group-III nitrides over the interface structure wherein the Al atoms are configured to be absorbed to the Si substrate and connect the Group-III nitrides and the SiₓN_{y} is configured to release mismatch stress generated by heteroepitaxy.

### CROSS-REFERENCE TO RELATED APPLICATIONS

The present application is a continuation of, and claims priority to, PCT/CN2014/081768 filed on Jul. 7, 2014, which claims priority to Chinese Patent Application No. 201310339115.9 filed on Aug. 7, 2013. The disclosures of these applications are hereby incorporated by reference in their entirety.

### BACKGROUND

Compared with sapphire and SiC substrates, Group-III nitrides epitaxy on Si substrate has many advantages: silicon based processing technologies are highly developed; high-quality, low-price and big-size Si substrates are available in the market; and Si substrates have good heat dispersion and can be easily removed after wafer-bonding. However, difficulties exist in Group-III nitrides epitaxy on Si substrates. For example, there are huge lattice mismatch and thermal mismatch between Si and Group-III nitrides, easily resulting in cracking of the epitaxial film; and Ga meltback etching may occur as Si reacts with Ga.

To solve the issue of film cracking, the Chinese Patent Application No. 201010137778.9 discloses method and structure of reducing LED epitaxial stress on Si substrates. According to that patent application, a silicon nitride or silicon dioxide layer is initially formed over the Si substrate surface through PECVD or sputtering, and afterwards a columnar or pitting circular structure is formed through photoetching. As it points out, in subsequent growth of Group-III nitrides, voids will be formed in the foresaid structure which help eliminate the tension between the film and the Si substrate. However, the processing technology disclosed in that patent application is complex, requiring additional equipment like PECVD and photoetching and thus incurring high processing cost.

### SUMMARY

The present disclosure provides an epitaxial structure of Group-III nitrides over the Si substrate and a forming method thereof. In this disclosure, Al atoms and in-situ formed SiₓN_{y} coexists in the interface between Si and the epitaxial Group-III nitrides.

The interface structure characterized by “coexistence of Al atoms and in-situ formed SiₓN_{y}” has the following advantages: 1) the provision of Al atoms which can be readily absorbed to Si is good for subsequent AlN epitaxy. In other words, Al atoms play the role of connecting the epitaxial Group-III nitrides and the Si substrate; 2) the SiₓN_{y} produced in the interface between Si and the epitaxial Group-III nitrides releases the mismatch stress caused by heteroepitaxy; 3) this structure can be easily formed in-situ through MOCVD, MBE or HVPE, and integrated into the Group-III nitrides epitaxy.

According to a first aspect of the present disclosure, an epitaxial structure of Group-III nitrides is provided, comprising a Si substrate and a Group-III nitrides layer disposed over the Si substrate, wherein: Al atoms and in-situ formed SiₓN_{y} are arranged in the interface between the Si substrate and the Group-III nitrides, wherein the Al atoms are configured to be absorbed to the Si substrate and to connect the Group-III nitrides layer and the SiₓN_{y} is configured to release the mismatch stress caused by heteroepitaxy.

Further, some regions of the Si surface are covered by the Al atoms and some other regions of the Si surface are covered by the SiₓN_{y}; and this structure of “coexistence of Al atoms and SiₓN_{y}” is cladded by an AlN epitaxial layer.

Further, the thickness of the AlN epitaxial layer denoted by H_{AlN} meets that 1 nm≦H_{AlN}≦500 nm.

Further, the Group-III nitrides comprises a single-layer or multi-layer of following Group-III nitrides : AlN, AlₓGa₁₋ₓN, GaN, In_{y}Ga_{1-y}N or (AlₓGa₁₋ₓ)_{1-y}In_{y}N, where, 0<x<1, 0<y<1.

According to a second aspect of the present disclosure, a method for fabricating an epitaxial structure of Group-III nitrides is provided, which includes the following steps: (1) providing a Si substrate; (2) forming an interface structure over the Si surface, wherein the interface structure is arranged with Al atoms and in-situ formed SiₓN_{y}, and both Al atoms and SiₓN_{y} are cladded by an AlN epitaxial layer; and (3) further grow Group-III nitrides on the foresaid structure, in which, the Al atoms are configured to be absorbed to the Si substrate and to connect the Group-III nitrides, and the SiₓN_{y} is configured to release the mismatch stress caused by heteroepitaxy.

In some embodiments, the interface structure of “coexistence of Al atoms and SiₓN_{y}” can be formed in-situ through the following three epitaxial sub-steps: (i) introducing in an Al source for an appropriate period of time T₁; (ii) closing the Al source and introducing in an N source for an appropriate period of time T₂; and (iii) introducing in the Al source and the N source simultaneously to form an AlN epitaxial layer of certain thickness. Specifically, in sub-step (i), T1 is configured such that some regions of the Si surface are covered by the Al atoms and some other regions of the Si surface are not covered with the Al atoms due to the short exposure to the Al source; in sub-step (ii), T2 is configured such that SiₓN_{y} is formed on the non-Al-covered regions of the Si surface, and that the Al-covered regions of the Si surface are protected from nitridation, and at the same time some of the Al atoms may be nitridated into AlN; , n; in sub-step (iii), T3 is configured such that the AlN epitaxial layer reaches a certain thickness in order to prevent the potential Ga meltback etching on the Si substrate.

An important aspect of this present disclosure is to determine the Al source exposure time T₁ in step (1), so that the Si surface is not entirely covered by the deposited Al atoms, thus leaving some Al-free regions, which can be nitridated into SiₓN_{y} in step (2) when the N source is introduced. T₁ is calculated as follows:

First, the upper limit T_{Al} of T₁ is the time during which the Si substrate surface is entirely covered by the Al atoms. However, it is much easier to obtain the AlN growth rate v than to obtain the T_{Al}, e.g., through a reflectivity oscillation curve in MOCVD or by a RHEED in-situ monitoring device in MBE. Detailed description follows about how to calculate the upper limit T_{Al} of T₁ by the aid of the AlN growth rate v.

By definition, T_{Al} means that the Si surface is just entirely covered by the Al atoms. If there was sufficient supply of the N source in the reaction chamber during T_{Al}, the Al source would react with the N source to generate AlN; and when the kinetic processes of this reaction like diffusion, decomposition, absorption, surface migration, desorption and so on were so idealized that during T_{Al} all the Al atoms covering Si surface were completely converted into AlN, the time for this idealized status was the upper limit of T_{Al}, i.e., time for growing a single layer of AlN, T_{AlN} Moreover, if the tension stress is ignored and the lattice constant of AlN at growth direction c=0.50 nm, it is easy to obtain T_{AlN}=c/v through the AlN growth rate. Where units of T_{AlN} and v are s and μm/h respectively, T_{AlN}=1.8/v. To sum up, the exposure time of Al source, T₁, should meet: 0<T₁<T_{Al}<T_{AlN}=1.8/v, i.e., 0<T₁<1.8/v.

Further, to expand the time window of supplying Al source in sub-step (i), it is required to deposit the Al atoms at a slow rate. That means, if sufficient N source was provided at this time, the AlN growth rate through reaction of the Al source and the N source would be slowed down accordingly; thus from 0<T₁<1.8/v, v should be small and the window of T₁ could be enlarged to improve the usability of the present disclosure. Generally, in sub-step (i) of supplying the Al source, it is appropriate to make v meet 0<v<1, and the growth conditions which guarantee a small v value can realize slow-rate Al atom deposition. For instance, the time window of step (i) can be enlarged through low-flow Al source.

Another important aspect is to obtain an interface structure of “coexistence of Al atoms and SiₓN_{y}” after closing the Al source is in sub-step (ii) which introduces in the N source for an appropriate period of time denoted by T₂. T₂ depends on different epitaxial methods and equipment. According to some embodiments where MOCVD is adopted, the T₂ meets 0<T₂<5/F_{NH3}, wherein, F_{NH3} is the NH₃ flow on each square centimeter of the substrate, and units of F_{NH3} and T₂ are slm/cm² and min respectively.

Then, in sub-step (iii) the Al source and the N source are provided simultaneously for a period of time T₃ to grow AlN of a certain thickness, so as to prevent the potential Ga meltback etching on the Si substrate. In general, T₃ should guarantee that the thickness of the AlN epitaxial layer, H_{AlN} meets 1 nm≦H_{AlN}≦500 nm.

The last step is to further grow the Group-III nitrides over the above structure. The Group-III nitrides may comprise a single-layer or multi-layer of following Group-III nitrides: AlN, GaN, InN, AlₓGa₁₋ₓN, AlₓIn₁₋ₓN, InₓGa₁₋ₓN or (AlₓGa₁₋ₓ)_{1-y}In_{y}N, where, 0<x<1, 0<y<1.

In addition, except for the foresaid growth methods like MOCVD, MBE or HYPE, other growth methods are also applicable.

### BRIEF DESCRIPTION OF THE DRAWINGS

FIG. 1 is a structural diagram of the epitaxial Group-III nitrides over the Si substrate according to the present disclosure. In the drawing: 10: Si substrate, 201: Al atom, 202: SiₓN_{y}, 20: AlN layer, 30: Group-III nitride layer. 201 and 202: the interface structure of “coexistence of Al atoms and SiₓN_{y}”.

FIG. 2 is a flow-time diagram of TMAl and NH₃ corresponding to the structure of “coexistence of Al atoms and SiₓN_{y}” produced in the interface between the Si substrate and the Group-III nitrides by MOCVD method.

### DETAILED DESCRIPTION

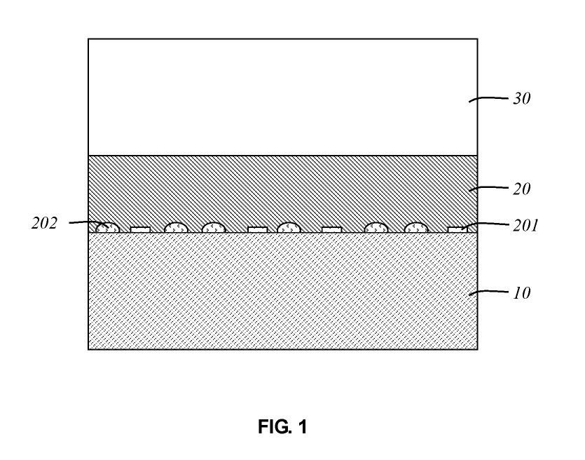

Refer to FIG. 1 for the structural diagram of the epitaxial Group-III nitride over the Si substrate according to the present disclosure. As shown in the figure, some regions of the surface of the Si substrate 10 are covered by the Al atoms 201 and some other regions by the SiₓN_{y} 202, and this structure of “coexistence of Al atoms and SiₓN_{y}” is cladded inside the AlN epitaxial layer 20. Then, the Group-III nitrides 30 are further grown over the above structure. The Group-III nitrides 30 comprise a single-layer or multi-layer of following Group-III nitrides: AlN, GaN, InN, AlₓGa₁₋ₓN, AlₓIn₁₋ₓN, InₓGa₁₋ₓN or (AlₓGa₁₋ₓ)_{1-y}In_{y}N, where, 0<x<1, 0<y<1.

The present disclosure will describe in detail taking MOCVD growth method as an example.

For the MOCVD growth method, the Al source and the N source are TMAl and NH₃ respectively. The interface structure of “coexistence of Al atoms and SiₓN_{y}” can be formed in situ mainly through the following three steps: step 1 introduces in the TMAl for an appropriate period of time T₁, such that some regions of the Si surface are covered with the Al atoms and other regions are not as the exposure time to TMAl is short; step 2 closes TMAl and opens NH₃ for an appropriate period of time T₂, thus the Si surface not covered with Al atoms will be nitrided into SiₓN_{y}, and those regions covered with Al atoms are free from nitridation, and meanwhile some Al atoms may be nitrided into AlN; in step 3, introducing in the TMAl and the NH₃ simultaneously for T₃ to grow AlN to a certain thickness, so as to prevent potential Ga meltback etching on the Si substrate.

In step 1, the TMAl introduction time T₁ should meet 0<T₁<1.8/v. To expand the time window of step 1 in the MOCVD, it is required to deposit the Al atoms at a slow rate, which is realized by controlling the growth conditions of step 1. In general, small v value and corresponding slow Al atom depositing can be realized through one or more such growth conditions as low-flow TMAl, high-pressure, or carrier gas with high H₂ ratio. Specifically, TMAl flow F_{TMAl} should meet: F_{TMAl}≦20 μmol/min·cm², wherein: F_{TMAl} is the TMAl flow over each square centimeter of substrate per minute and the unit is μmol/min·cm²; high pressure P should meet: P>30 Torr; and carrier gas with high H₂ ratio should meet: F_{H2}/(F_{H2}+F_{N2})≧0.3, wherein: F_{H2} and F_{N2} are flows of carrier gases H₂ and N₂ respectively.

In step 2, as to the appropriate time T₂ to introduce in NH₃ after closing the TMAl, generally for MOCVD, the structure of “coexsistence of Al and SiₓN_{y}” can form well where T₂ meets 0<T₂<5/F_{NH3}, wherein, F_{NH3} is the NH₃ flow on each square centimeter of the substrate, and units of F_{NH3} and T₂ are slm/cm² and min, respectively.

In addition, as to the AlN epitaxial time T₃ in step 3, in general, T₃ should guarantee that the thickness of the AlN layer, H_{AlN,} meets 1 nm≦HAlN≦500 nm.

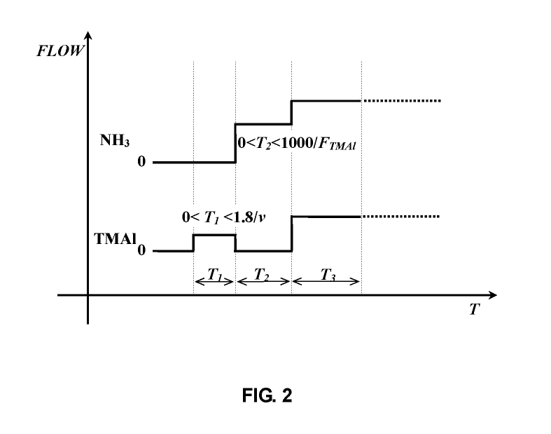

Refer to FIG. 2 for the flow-time diagram of TMAl and NH₃ corresponding to the above three steps.

Refer to steps below for growing Group-III nitrides over the Si substrate by MOCVD: a) Si surface pre-processing; b) H₂ high-temperature processing in chamber; c) epitaxy of the interface structure of “coexistence of Al atoms and SiₓN_{y}”; and d) further epitaxy of the Group-III nitrides.

a) surface pre-processing of Si substrate outside the reaction chamber;

Pre-processing for the Si substrate surface is performed according to standard procedures of RCA clean. The RCA clean mainly comprises the three sub-steps below: i. removal of the organic contaminants on Si surface with mixed solution of NH₄OH and H₂O₂; ii. removal of thin oxide layer with HF solution; and iii. removal of metal ionic contamination with mixed solution of HCl and H₂O₂. In addition, DI water cleaning is needed after each step.

b) High-temperature H₂ baking in the MOCVD reaction chamber;

After RCA clean, place the Si substrate in the MOCVD reaction chamber, and raise the temperature to about 1,100° C. for further baking and cleaning of the Si substrate in H₂ ambient.

c) Epitaxy of the interface structure of “coexistence of Al atoms and SiₓN_{y}”;

This structure is formed mainly through the three steps below:

I. Introduction of TMAl for T₁.

Under grown conditions of 1,100° C., 50 Torr and F_{H2} (F_{H2}+F_{N2})=0.5, where the Al source TMAl flow per square centimeter of substrate is 5 μmol/min·cm² and the N source NH₃ is sufficient, the corresponding AlN growth rate by MOCVD is v=0.1 μm/h and correspondingly 0<T₁<1.8/v, i.e., 0<T₁<18 s. Therefore, under the above growth conditions, the TMAl can be turned on in step 1 for T₁=8 s.

II. Introduction of NH₃ for T₂ after closing TMAl.

Where the N source NH₃ flow per square centimeter of substrate is 0.2 slm/cm², the time T₂=5 min to make Si surface partially deposited with Al atoms.

III. Simultaneous opening of TMAl and NH₃ for T₃ for AlN epitaxy.

Under the growth conditions where AlN growth rate is about 0.5 μm/h, grow AlN for T₃=24 min and obtain AlN about 200 μm.

d) Further epitaxy of the Group-III nitrides over the above structure. The Group-III nitrides comprises a single-layer or multi-layer structure of following Group-III nitrides: AlN, GaN, InN, AlₓGa₁₋ₓN, AlₓIn₁₋ₓN, InₓGa₁₋ₓN or (AlₓGa₁₋ₓ)_{1-y}In_{y}N, where, 0<x<1, 0<y<1.

All references referred to in the present disclosure are incorporated by reference in their entirety. Although specific embodiments have been described above in detail, the description is merely for purposes of illustration. It should be appreciated, therefore, that many aspects described above are not intended as required or essential elements unless explicitly stated otherwise. Various modifications of, and equivalent acts corresponding to, the disclosed aspects of the exemplary embodiments, in addition to those described above, can be made by a person of ordinary skill in the art, having the benefit of the present disclosure, without departing from the spirit and scope of the disclosure defined in the following claims, the scope of which is to be accorded the broadest interpretation so as to encompass such modifications and equivalent structures.

1. A Group-III nitrides epitaxial structure, comprising:
a Si substrate, and
a Group-III nitrides layer disposed over the Si substrate,
wherein an interface structure between the Si substrate and the Group-III nitrides layer is arranged with:
Al atoms, configured to be absorbed to the Si substrate and connect the Group-III nitrides layer; and
SiₓN_{y}, configured to release mismatch stress caused by heteroepitaxy.

2. The structure of claim 1, wherein:
some regions of surface of the Si substrate are covered by the Al atoms;
some other regions of the surface of the Si substrate are covered by the SiₓN_{y}; and
the interface structure is cladded inside by an AlN layer.

3. The structure of claim 2, wherein a thickness of the AlN layer H_{AlN} is between around 1 nm and around 500 nm.

4. The structure of claim 1, wherein: the Group-III nitrides layer comprises at least one sub-layer of a Group-III nitride, selected from a group consisting of AlN, GaN, InN, AlₓGa₁₋ₓN, AlₓIn₁₋ₓN, InₓGa₁₋ₓN and (AlₓGa₁₋ₓ)_{1-y}In_{y}N, where 0<x<1, 0<y<1.

5. A method of fabricating a Group-III nitrides epitaxial structure, comprising the steps of:
(1) providing a Si substrate;
(2) forming an interface structure over surface of the Si substrate, wherein the interface structure is arranged with Al atoms and SiₓN_{y}, and the Al atoms and the SiₓN_{y} are cladded by an AlN layer; and
(3) growing a Group-III nitrides layer over the interface structure;
wherein:
the Al atoms are configured to be absorbed to the Si substrate and connect the Group-III nitrides layer, and the SiₓN_{y} is configured to release mismatch stress caused by heteroepitaxy.

6. The method of claim 5, wherein the interface structure in step (2) is formed in situ, and step (2) comprises the sub-steps of:
(i) introducing in an Al source for a period of time T₁;
(ii) introducing in an N source for a period of time T₂ after closing the Al source; and
(iii) simultaneously introducing in the Al source and the N source for a period of time T₃ to form the AlN layer.

7. The method of claim 6, wherein:
in sub-step (i), T₁ is configured such that some regions of the surface of the Si substrate are covered by the Al atoms and some other regions of the surface of the Si substrate are not covered with the Al atoms;
in sub-step (ii), T₂ is configured such that the SiₓN_{y} is formed on non-Al atoms covered regions of the surface of the Si substrate, and that Al atoms covered regions are protected from nitridation, and that some of the Al atoms are nitrided into AlN; and
in sub-step (iii), T₃ is configured such that the AlN layer reaches a certain thickness so as to prevent Ga meltback etching on the Si substrate.

8. The method of claim 6, wherein in sub-step (i), 0<T₁<1.8/v, where v means a growth rate of the AlN layer if meanwhile supplied with sufficient N source under same growth conditions as only introducing in Al source and no N source, and units of v and T₁ are μm/h and s respectively.

9. The method of claim 8, wherein in sub-step (i): 0<v<1, where, unit of v is μm/h.

10. The method of claim 6, wherein in sub-step (iii), T₃ is configured such that a thickness of the AlN layer H_{AlN} is between around 1 nm and around 500 nm.

11. The method of claim 5, wherein the interface structure in step (2) is formed in situ through MOCVD, and step (2) comprises the sub-steps of:
(a) introducing in TMAl for a period of time T₁;
(b) introducing in NH₃ for a period of time T₂ after closing TMAl;
(c) simultaneously introducing in TMAl and NH₃ for a period of time T₃ to form the AlN layer.

12. The method of claim 11, wherein in sub-step (a), 0<T₁<1.8/v, where v means a growth rate of the AlN layer if meanwhile supplied with sufficient N source under same growth conditions as only introducing in Al source and no N source, and units of v and T₁ are μm/h and s respectively.

13. The method of claim 12, wherein in sub-step (a): 0<v<1, where, unit of v is μm/h.

14. The method of claim 13, wherein growth condition in sub-step (a) comprises at least one of:
a low TMAl flow, wherein F_{TMAl}≦20 μmol/(min·cm²), where F_{TMAl} is TMAl flow over each square centimeter of the Si substrate per minute;
a high pressure, wherein P≧30 Torr, where P is pressure; or
a high H₂ carrier gas ratio, wherein F_{H2}/(F_{H2}+F_{N2})≧0.3, where F_{H2} and F_{N2} are flows of carrier gases H₂ and N₂ respectively.

15. The method of claim 11, wherein in sub-step (b), 0<T₂<5/F_{NH3}, where F_{NH3} is NH₃ flow over each square centimeter of the Si substrate, and units of F_{NH3} and T₂ are slm/cm² and min respectively.

16. The structure of claim 1, wherein: the SiₓN_{y} is formed in situ.

17. The method of claim 5, wherein: the Group-III nitrides layer in step (3) comprises at least one sub-layer of a Group-III nitride, selected from a group consisting of AlN, GaN, InN, AlₓGa₁₋ₓN, AlₓIn₁₋ₓN, InₓGa₁₋ₓN and (AlₓGa₁₋ₓ)_{1-y}In_{y}N, where 0<x<1, 0 <y<1.

18. The method of claim 5, wherein: the SiₓN_{y} in step (2) is formed in situ.

19. The method of claim 5, wherein in step (2) the interface structure is formed in situ through MOCVD, MBE or HYPE.
